(19) United States
(12) Patent Application Publication
(10) Pub. No.: US 2015/0113344 A1
(43) Pub. Date: Apr. 23, 2015

(54) TESTING METHOD, TESTING APPARATUS AND CIRCUIT FOR USE WITH SCAN CHAINS

(71) Applicant: STMicroelectronics (Research & Development) Limite d, Marlow (GB)

(72) Inventor: Gary Morton, Bristol (GB)

(21) Appl. No.: 14/517,673

(22) Filed: Oct. 17, 2014

(30) Foreign Application Priority Data
Oct. 18, 2013 (GB) 1318480.9

(51) Int. Cl. G01R 31/3177

(52) U.S. Cl. CPC G01R 31/3177
USPC 714/727

(57) ABSTRACT

A scan chain includes a plurality of scan chain blocks coupled together in series and reference circuitry inserted before one of the plurality of scan chain blocks. The reference circuitry, in a scan mode of operation, receives a scan input signal. In a test data capture mode of operation, the reference circuitry receives a known test signal value, and, in a scan out mode of operation, outputs the known test signal value to the one scan chain block of the plurality of scan chain blocks.

### BACKGROUND

1. Technical Field

This disclosure relates to circuits, methods and articles which may, for example, be used to test devices such as integrated circuits or dies.

2. Description of the Related Art

Despite advances in semiconductor process technology integrated circuits can be manufactured with faults. Just a single fault can render a circuit unusable. Manufacturers have implemented various techniques to identify where these circuits are faulty.

Integrated circuits can be tested by automated test equipment (ATE). The automated test equipment (ATE) typically works in response to a test sequence or input provided from an automatic test pattern generator (ATPG) which when applied to the circuit under test allows a distinction to be made between correct circuit behavior and faulty circuit behavior. ATPG patterns can in practice be used to attempt to detect faults such as a “stuck-at fault” where a signal line in the circuit is assumed to be stuck at a fixed logic value regardless of the inputs supplied to the circuit.

### BRIEF SUMMARY

According to some embodiments, a circuit comprises: a first scan chain block having an input configured to receive a first output from a second scan chain block in scan mode and a known test signal value in test data capture mode; and a second output configured to provide said known test signal value to a third scan chain block in a scan out mode.

The second output may output the first output from the second chain block when the known test signal value has been output to the third scan chain block.

The first scan chain block may be configured to provide said second output.

The circuit may comprise retiming circuitry configured to receive said known test signal value from said first scan chain block and to provide said second output.

The retiming circuitry may comprise a lock-up latch.

The known test signal may be received, in use, from a dedicated pin of a device in which said circuit is provided.

The known test signal may be is received, in use, from a test register of a device in which said circuit is provided.

A scan chain may comprise one or more of the circuits as described above.

The scan chain may comprise first and second of said circuits, said first circuit configured to receive a first value of said known test signal in said test data capture mode and said second circuit is configured to receive a second value, which is the inverse of the first value of said known test signal in said test data capture mode.

The scan chain may comprise an invertor configured to receive said first value of said known test signal and to output said second value of said known test signal.

An integrated circuit or die may comprise the circuit or scan chain as discussed above.

The integrated circuit or die may comprise said test register.

According to some embodiments, a testing apparatus comprises; an input configured to receive information about a comparison between one or more test pattern outputs provided by a scan chain of a device under test and expected test pattern outputs, and an analyzer configured to analyze said information to determine if said information indicates that a known scan chain block in said chain has a known test signal value which is different from the expected test pattern output for said known scan chain block.

According to some embodiments, a testing method comprises; receiving information about a comparison between one or more test pattern outputs provided by a scan chain of a device under test and expected test pattern outputs, and analyzing said information to determine if said information indicates that a known scan chain block in said chain has a known test signal value which is different to the expected test pattern output for said known scan chain block.

A computer program comprising program code means adapted to perform the method may also be provided. The computer program may be stored and/or otherwise embodied by means of a carrier medium.

In the above, many different embodiments have been described. It should be appreciated that further embodiments may be provided by the combination of any two or more of the embodiments described above.

In an embodiment, a device comprises: a plurality of scan chain blocks coupled together in series; and reference circuitry inserted before one of the plurality of scan chain blocks and configured to: in a scan mode of operation, receive a scan input signal; in a test data capture mode of operation, receive a first known test signal value; and in a scan out mode of operation, output the first known test signal value to the one scan chain block of the plurality of scan chain blocks. In an embodiment, the reference circuitry is configured to, in the scan out mode of operation, output the received scan input signal to the one scan chain block after outputting the first known test signal value to the one scan chain block. In an embodiment, said reference circuitry comprises a scan chain block of the plurality of scan chain blocks. In an embodiment, the reference circuitry comprises a lock up latch configured to receive said first known test signal value from the scan chain block of the reference circuitry. In an embodiment, the device comprises a dedicated input pin, wherein said reference circuitry is configured to, in the test data capture mode of operation, receive said first known test signal value through the dedicated pin. In an embodiment, the device comprises a test register, wherein said reference circuitry is configured to, in the test data capture mode of operation, receive said first known test signal value from the test register. In an embodiment, the device comprises: second reference circuitry inserted before another scan chain block of the plurality of scan chain blocks and configured to: in the scan mode of operation, receive a second scan input signal; in the test data capture mode of operation, receive a second known test signal value; and in the scan out mode of operation, output the second known test signal value to the another scan chain block of the plurality of scan chain blocks. In an embodiment, the second known test signal value is an inverse of the first known test signal value. In an embodiment, the device comprises an invertor configured to receive said first known test signal value and to output said second known test signal value. In an embodiment, an integrated circuit includes the plurality of scan chain blocks and the reference circuitry. In an embodiment, a semiconductor die includes the plurality of scan chain blocks and the reference circuitry. In an embodiment, the plurality of scan chain blocks form a first scan chain of the device and the device comprises: a second plurality of scan chain blocks coupled together in series and forming a second scan chain of the device; and reference circuitry of the second scan chain inserted before one of the second plurality of scan chain blocks and configured to: in the scan mode of operation, receive a second scan input signal; in the test data capture mode of operation, receive a second known test signal value; and in a scan out mode of operation, output the second known test signal value to the one scan chain block of the second plurality of scan chain blocks.

In an embodiment, a circuit design tool is configured to generate a circuit design including one or more embodiment of devices as disclosed herein.

In an embodiment, a system comprises: an input configured to receive information about a comparison between one or more test pattern outputs of a scan chain of a device under test and expected test pattern outputs; and circuitry configured to determine whether a known reference point of the scan chain has a known test signal value which different from an expected test signal value based on said received information about the comparison. In an embodiment, the system comprising a comparator configured to compare the one or more test pattern outputs to the expected test pattern outputs. In an embodiment, the system comprises at least one signal translator coupled between the comparator and the circuitry. In an embodiment, the circuitry is configured to generate control signals to control loading of the known test signal value into the known reference point of the scan chain.

In an embodiment, a method comprises: receiving, by one or more configured processing devices, information about a comparison between one or more test pattern outputs of a scan chain of a device under test and expected test pattern outputs; and determining, by the one or more configured processing devices, whether a known reference point of the scan chain has a known test signal value which different from an expected test signal value based on said received information about the comparison. In an embodiment, the method comprises comparing the one or more test pattern outputs to the expected test pattern outputs. In an embodiment, the method comprises loading of the known test signal value into the known reference point of the scan chain.

In an embodiment, a non-transitory computer-readable memory medium's contents, when accessed by a processing system, configure the processing system to perform a method, the method comprising: analyzing a comparison of one or more test pattern outputs of a scan chain of a device under test and expected test pattern outputs; and determining whether a known reference point of the scan chain has a known test signal value which different from an expected test signal value based on the analysis. In an embodiment, the method comprises comparing the one or more test pattern outputs to the expected test pattern outputs. In an embodiment, the method comprises loading of the known test signal value into the known reference point of the scan chain.

Various other aspects and further embodiments are also described in the following detailed description.

### BRIEF DESCRIPTION OF THE SEVERAL VIEWS OF THE DRAWINGS

For a better understanding of some embodiments, reference will now be made by way of example only to the accompanying Figures in which:

FIG. 1 schematically shows a scan chain;

FIG. 2 schematically shows a test environment;

FIG. 3 shows a first example of a reference block for inclusion in a scan chain;

FIG. 4 shows a second example of reference blocks for inclusion in a scan chain; and

FIG. 5 shows a method of some embodiments.

### DETAILED DESCRIPTION

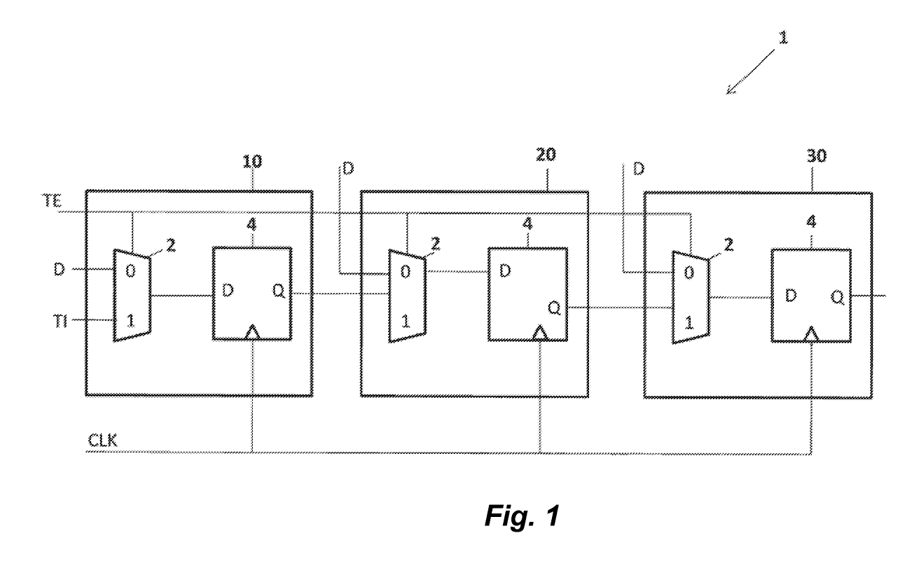

Some embodiments may have scan chains for testing system on chip circuits or the like. Reference is made to FIG. 1 which schematically shows an integrated circuit or die 1 with a scan chain. The scan chain is schematically shown in FIG. 1. The scan chain comprises a plurality of scan blocks. In the example shown in FIG. 1, three scan blocks, 10, 20 and 30 are shown. In practice, the scan chains provided will be much larger. A scan chain can be any length. For example, some scan chains may have a very large number of scan blocks. Some scan chains may have tens of thousands of scan blocks.

Each scan block is provided with a flip-flop or similar element. In some embodiments, the flip-flop may be a D-type flip-flop. Each flip-flop 4 receives a clock signal at its clock input. In the example shown in FIG. 1, a common clock signal is applied to each of the flip-flops. However, it should be appreciated that in some embodiments, different flip-flops may receive different clock signals. Different ones of the scan blocks may be in different clock domains.

Each scan block comprises a multiplexer 2. The multiplexer 2 has one input which is configured to receive data D. The other input is configured to receive a test input TI. The multiplexer 2 of the first scan block 10 is arranged to receive test data from the test data source. This data comprises a test vector in the form of a stream of data which is clocked through the serially connected flip-flops. Thus, the output of each flip-flop is connected to the test input of the next scan block and so on.

In order to put the scan chain into the scan mode, a test enable signal is set to the scan mode. This causes the multiplexers 2 to select the test input data as the input to the flip-flop 4. The test vector is then scanned into this scan chain. In other words, in each successive clock cycle, the vector is shifted by one bit through the scan chain. At the end of the scan in mode, each flip-flop will have its respective bit of the test vector. The test enable signal is then deasserted.

The chip is put into the functional mode configuration which means that the data input of each multiplexer is selected. The outputs of functional circuitry are then captured by the respective flip-flops. The scan chain is then put back in to the test mode and the values which are captured by the flip-flops are clocked out. This can be done at the same time that a new test vector is input.

Scan testing is used for testing digital integrated circuits. ATPG tools from CAD (computer aided design) vendors are used to generate the scan test patterns used with arrangements such as shown in FIG. 1.

VLSI (very large scale integration) testers are used to apply these scan test patterns to the device under test (DUT). During the development of the test program or during the testing of first silicon, or during the analysis of production issues, one or more devices are data logged. This may generate information such as a text file containing diagnostic failure data.

Some embodiments provide a circuit to be added to the scan test architecture of an IC (integrated circuit). This circuit may aid in the analysis of scan test failures. The circuit may allow the determining with certainty which are the failing flip-flops (that is flip-flops containing data indicative of a failure), using information such as the data contained in the datalog.

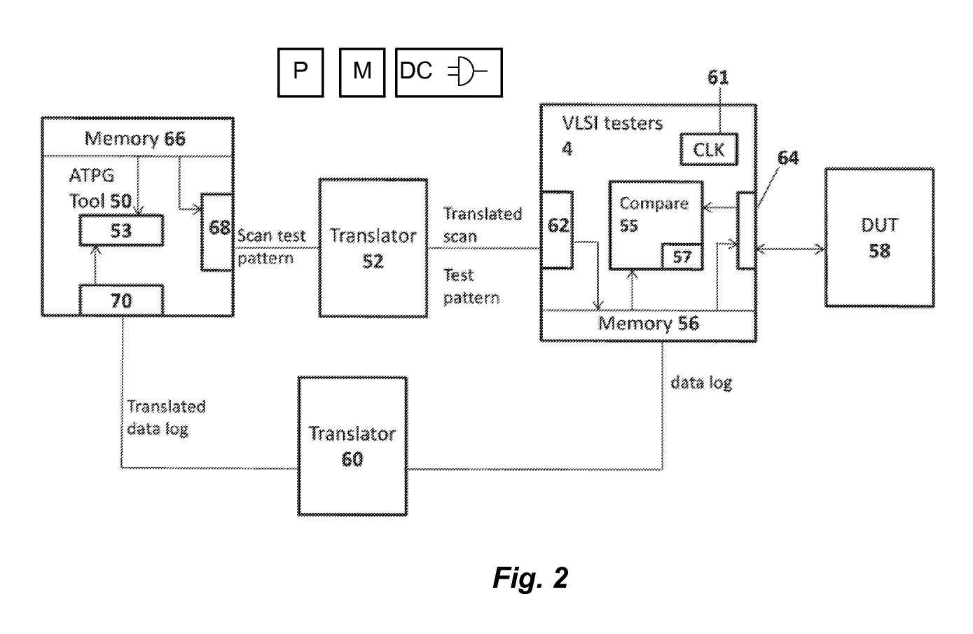

Reference is now made to FIG. 2 which schematically shows a testing arrangement. An ATPG tool 50 is provided. The ATPG tools create scan test patterns which can be saved out, for example in one or more industry standard formats. WGL (wave generation language) and STIL (standard test interface language) are two examples of industry standard file formats which are defined. For example STIL is defined in IEEE P1450.1. The test patterns may be stored in a memory 66 of the ATPG tool.

However, many VLSI testers cannot directly use these standard file formats or other outputs of the ATPG tool. The tester manufacturer or third party vendors may supply tools which read in the scan patterns from the ATPG tool, and then write out one or more files in the specific format required by the specific tester. Accordingly a translation function 52 is provided between the ATPG tool 50 and the VLSI tester 54. The ATPG tool has an output 68 from which the test patterns are output to the translator.

The ATPG created scan test patterns are composed of multiple vectors. A vector may correspond to one clock cycle, and contains the test values (for example both drive and compare) for a set of channels which may correspond one to one to the pins on the IC being tested.

The VLSI tester 54 is used to apply scan test patterns via an interface 64 to the IC to be tested 58. The testing of an IC is performed by a test program. A test program may be made up from a set of DC tests and test patterns. The test patterns may include one or more of patterns testing the IC configured in the scan test mode, patterns testing the IC with the IC configured in a device specific test mode, and patterns testing the IC in its normal functional mode.

The VLSI tester 54 receives from the translator the translated test patters via an interface 62 and stores the (translated) test patterns in a test vector memory 56. Each test vector may contain one or more values which determine whether the pin electronics for each channel (which connect to the pins of the IC) generate high or low drive data, generate a high going or low going clock pulse, test for a high value, a low value, or a tristate value, or do not drive and do not test in each cycle.

There is normally one to one correspondence to the vectors found in the ATPG scan test patterns and the translated data stored in the test vector memory 56 of the tester.

A master clock source 61 (which may be programmable) applies each set of data from the test vector memory to the device under test (DUT), until the vectors are exhausted. This may be indicated by a special value, terminal count, opcode or in any other suitable way.

The test vectors stored in the memory 56 of the tester 54 are applied by the tester 54 to the device under test. The response to each test vector is read out by the VLSI tester via the interface 64 and compared by a comparator 55 of the VLSI tester to an expected response stored in the memory 56. In some embodiments, the comparison carried out by the comparator may be done dynamically as the test vector is read in. If the response of the device to the stimulus from the test vector memory matches the expected values also found in the test vector memory, the DUT is considered to have passed this test.

The expected response is provided by the ATPG tool. The expected response will also be translated by the translator before being provided to the tester 54 and stored in the memory 56. The expected response may be provided with the test patterns or separately from the test patterns.

In some embodiments the memory 56 may be provided by a plurality of memories.

There may be many reasons why the application of a scan test pattern to a DUT would result in a fail result. In the cases where an analysis of the cause of the failure of the scan test pattern is required, the VLSI tester 54 will generate a datalog or other suitable information. In some embodiments, the datalog may be generated by a processing function 57 of the comparator 55. Alternatively or additionally, in other embodiments, one or more separate processors may be provided to generate the datalog. The processing function or processors are provided by suitable processing circuitry.

The datalog may be a file which contains fail information. The file may be a text file. Datalog formats can vary from each tester manufacturer. A datalog may contain one or more of a list of channels/pins which have had one or more mis-compares, the cycle number of each fail, together with the actual data value, sometimes giving the expected data value.

In any scan test pattern there might be thousands to many millions of compares across all the pins over all the cycles. Correspondingly in a datalog, there might be single fail or millions of fails. Where there is a large number of fails over many pins, this is normally attributed to a badly manufactured or faulty device. An interesting case is where the number of mis-compares is only over a small number of channels/pins and is of a limited number that might be reasonably analyzed.

Some ATPG tools have facilities for the analysis of scan failures. After reading in the scan test fails (for example in an ATPG specific non-standard format) via input 70 and using the original scan test pattern, the ATPG tool performs an analysis to try to diagnose the cause of the fail. The ATPG tool may assume that the fails are caused by one or more stuck-at faults in the silicon, and may try to map the scan test fails to a specific (stuck-at) net in the IC design. It is not unusual for a single stuck-at fault to manifest itself as causing two or more flip-flops to capture the incorrect data value.

The information or datalog may be converted by a translator 60 to the file format expected by the ATPG tool. The channel/pin name may be a text mapping.

One problem which may need to be addressed may be the alignment of the reported failing tester cycle, and the cycle or offset used by the ATPG tool.

Scan fails may alternatively or additionally be analyzed manually. Due to the correspondence of each scan out bit tested to a specific flop, it is diagnostic to extract from the datalog a list of failing flops inside the design. It is often found that the same flop fails many times. Patterns of failing flops are often seen, which are diagnostic in understanding the root cause of the failures (e.g., stuck-at fault, timing race, etc.).

During the analysis the problem faced by a test engineer is the “out by one or a few” mistake. Similar problems occur with the analysis by automated tools. Scan test patterns are constructed from a series of phases of scan testing. The first vectors put the device into the scan test mode, and this is called the initialization phase and may be executed only once. It is useful to know the number of cycles taken by the initialization. This is generally well defined.

The next phase is a scan load, whereby all scan chains are loaded with test data to be applied to the internal circuitry. This takes a known and deterministic number of cycles. The next phase is the capturing of the response of the internal circuitry to the applied data. This also takes a known and deterministic number of cycles.

However some ATPG tools can add one or more additional padding cycles between one load cycle and the capture cycle. These one or more clock cycles may be used to compensate one or more factors such as different ones of the scan chains being in different clock domains. The final phase is the scan unload, whereby all the captured data is unloaded or shifted out of all the scan chains, where it is compared against the expected values by the tester. The sequence, scan load, capture and scan unload repeats many times in order to achieve a high fault coverage. Any error in incorrectly assuming a number of padding cycles even if only out by one cycle, can cause problems in analyzing the datalog.

Scan load and scan unload may be merged together so that while one set of data is being unloaded from the scan chain, the next set of data is being loaded into the scan chain.

ATPG tools can write out a list of all flip-flops which compose each scan chain. It is usually known which chains connect to which scan outputs, and this is not usually a source of mistakes during scan fail analysis.

When analyzing a datalog, one problem may be the translation of the cycle number to the scan load/unload number and offset into the scan unload, and from there to a named flip-flop using the scan cell listing as a cross reference.

Even though scan shift length and number of initialization and capture cycles should be known, they can vary from scan test pattern to scan test pattern. It is not unusual to have a number of iterations before the list of failing flip-flops appears to be meaningful, when it is not unusual to see patterns in the list of failing flops, such as all flip-flops in the same register, or only flip-flops in a specific block. In the case of a relatively few number of fails in the datalog, there may be a problem of “out by one or a few” errors. In other words, a flip-flop may be identified as the source of the fault, but it may be difficult to know exactly which one of the flip-flops of the scan chain is the one containing the fault.

The embodiment of a testing arrangement shown in FIG. 2 includes circuitry to implement the various blocks of the testing arrangement. As illustrated, the circuitry comprises one or more processors P, one or more memories M, and discrete circuitry DCR, such as logic gates, transistors, etc.

Some embodiments provide additional circuitry which is inserted in the scan chain in order to allow confirmation of the correct analysis of the failing scan flip-flops. In other words, this additional circuitry provides a reference. This is achieved by the addition of one or more flip flops at a known position in the scan chain which can be forced to fail under test user control. The additional circuitry may be inserted, for example into the scan chain of FIG. 1.

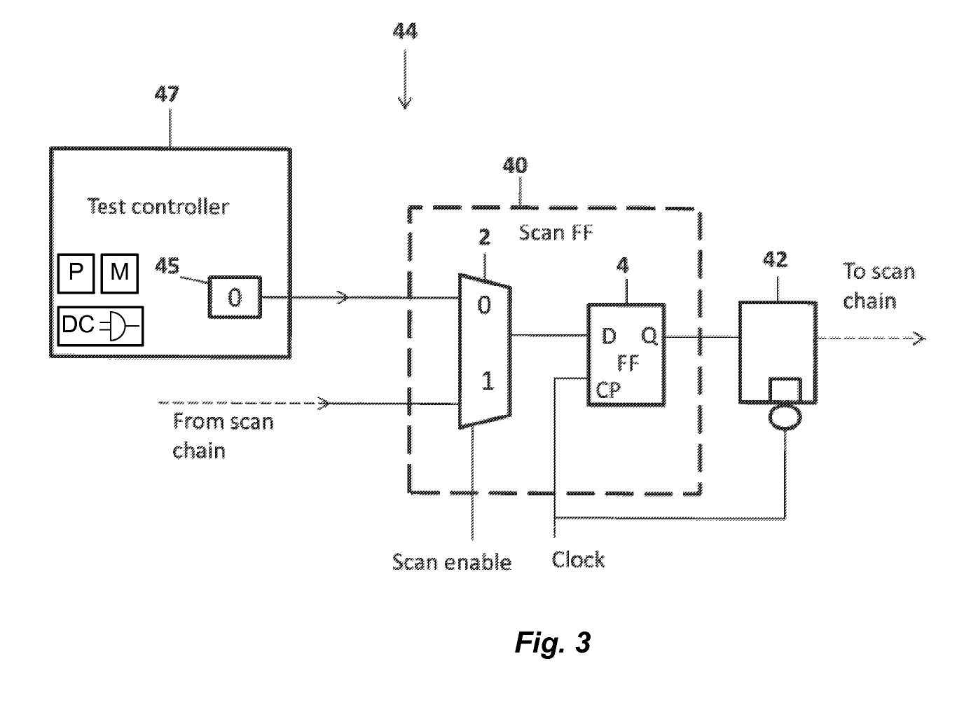

Reference is made to FIG. 3. The additionally diagnosis circuitry 44 comprises a scan block 40 comprising a multiplexer 2 and flip-flop 4 as described in relation to FIG. 1. This reference arrangement is inserted into the scan chain. Thus the multiplexer will receive a scan input from a previous scan chain block, if present or will be the first scan block of the scan chain. Thus one or more diagnosis blocks are added to the design and connected into the I scan chain or chains. Any suitable scan shift clock may be used as the clock input.

In order to avoid any timing issues between the diagnosis circuitry and the next scan block in the scan chain, the diagnosis circuitry also comprises retiming circuitry. In some embodiments, the retiming circuitry may be provided by a lockup latch 42 which is provided after the scan block 40. The lock up latch receives the same clock as the flip-flop of the scan block 40. The output of the flip-flop of the scan block 40 is input to lock up latch. The output of the lock up latch is input to the next scan block in the scan chain. A negative edge clocked flip-flop or similar may be used as an alternative to a lock-up latch in some embodiments.

The source of the connection to the data input of the multiplexer is an internal signal whose value is known, but which can be changed interactively on the tester.

One option is to provide a dedicated top level pin of the device but this may be undesirable in arrangements where as many pins as possible are required for scan inputs, scan outputs and scan clocks. However, there may be implementations where this provides advantages.

An IC capable of being scan tested, may have a module or circuitry 47 which allows the device to be put into the scan testing mode, by asserting one or more internal test signals. It is these test signals which are loaded with a ‘1’ during the test initialization. The internal test signals normally would map to one or more test registers implemented to support testing of the IC. An additional bit in one of these registers may be added, which will generate the internal test signal to be connected to the data input of the or each of the multiplexers of the diagnosis circuitry 44. This test register bit is schematically shown in FIG. 3 and is referenced 45.

In some embodiments, at least one diagnosis circuitry is added for each top level scan chain. The diagnosis circuitry may be at any one or more positions in the scan.

In the ATPG tool, the test initialization should be augmented to set the internal diagnosis test signal to ‘0’ (or ‘1’ may be alternatively chosen, it is a matter of design choice). This would entail loading the corresponding test register bit with the same value. Scan test patterns may be generated in the normal manner.

During scan testing of any IC, the diagnosis circuitry 44 will capture the same value as the value loaded into the bit in the test register 45. The flip-flop of the diagnostic circuitry will always scan unload this same value, unless there is a fault in the test register bit or connection from the test register bit to the diagnosis flop-flop. The flip-flop of the diagnosis circuitry is effectively invisible during scan testing.

When it is required to generate a datalog of a scan test pattern for later offline diagnosis, particularly if the number of fails is small, there will be a chance of the “out by one or a few” type analysis error. Using the tools/features of the tester, it is possible to interactively edit the test vector memory, specifically, the bit in the test vector memory which corresponds to the value which is loaded into the test register and generates the diagnosis test signal. It may be inverted from its initial value. By inverting the value which is loaded into register 45 during test initialization, the value unloaded from the diagnosis circuitry in the scan unload operation is inverted with respect to the normal expected value in the scan unload test vector.

When the scan pattern is run and the datalog generated, the number of fails will have increased by at most the number of diagnosis circuitry multiplied by the number of scan load/unloads. In some cases the ATPG tool does not test the diagnosis flops-flops (in every load/unload), so the number of additional fails might be lower than expected. The datalog is augmented with fail data for each of the diagnosis circuitry.

When the datalog is analyzed, the diagnostic circuitry should be flagged as failing. This means that it possible to use this as a reference for other failing scan blocks. If the diagnostic circuitry is not flagged as failing, then this may point to a problem in the analysis.

This may be caused by one or more of: wrong number of cycles for the test initialization, resulting in an offset by the difference between the actual number of test initialization cycles and the expected number of cycles entered into the tool; or the wrong number of cycles for the scan shift plus capture, which allows the load/unload to be calculated; and the wrong number of padding cycles.

The embodiment of a test controller 47 shown in FIG. 3 includes circuitry to implement the test controller. As illustrated, the circuitry comprises one or more processors P, one or more memories M, and discrete circuitry DCR, such as logic gates, transistors, etc.

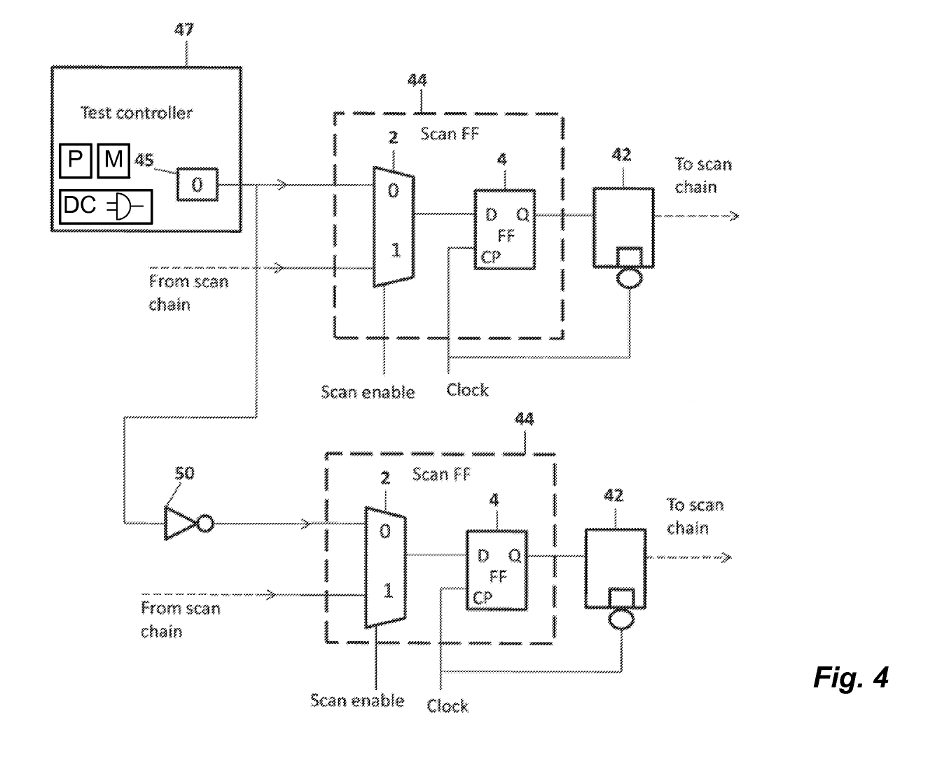

A second example will now be described in relation to FIG. 4. The arrangement of FIG. 4 shows two diagnosis circuitry 44, each of which is generally as shown in FIG. 3. It should be appreciated that each of the diagnosis circuitry may be provided in the scan chain, one after another or separated by one or more other scan blocks. In some embodiments, the diagnosis circuitry may be provided in different scan chains.

Using an inverter 50, the diagnosis test signal is inverted before connecting to the data in input of the multiplexer 2 of the second diagnosis circuitry. In other words one or more of the diagnosis circuitry will receive the test signal and one or more of the diagnosis circuitry will receive the inverted test signal.

In the above example where the test register bit is loaded with a ‘0’, in the case of the first diagnosis circuitry the tester will be testing for the ‘0’ (expect ‘0’), but in the case of the second diagnosis circuitry the tester will testing for ‘1’ (expect ‘1’). When the diagnosis test signal is set to ‘1’, the top flop will fail with actual data ‘1’/expected ‘0’, and the bottom flop will fail with actual data ‘0’/expected ‘1’. The different values may in some embodiments help distinguish from flip-flops which fail close in position in the scan chain to the diagnosis flip-flops.

In some embodiments, the invertor may be omitted and instead two register bits are provided, one holding a ‘1’ and the other holding a ‘0’. One or more diagnosis circuitry would be arranged to receive a ‘1’ and one or more diagnosis circuitry would be arranged to receive a ‘0’.

In some embodiments a multiplexer may be provided to provide a ‘1’ value to the diagnosis circuitry for one or more scan tests and a ‘0’ to the same diagnostic circuitry for one or more other scan tests. This may employ the presence of an inverter or two register bits.

The arrangement of FIG. 4 may be diagnostic in the case of compressed scan patterns. These types of patterns may be CAD vendor specific. A XOR (exclusive-OR) tree is used to compress down the scan unload data stream. It is usually left to the ATPG tool to perform the analysis. This once again can be susceptible to “out by one or more” errors. When correctly configured, with the right scan cycle values, ATPG tools may diagnose a stuck-at fault on the output of the diagnosis bit in the test register.

Alternatively or additionally the arrangement of FIG. 4 may be useful where one test value may be easier to identify as a fail.

Some embodiments use a datalog. It should be appreciated that the results of the comparison may be provided in any suitable other form.

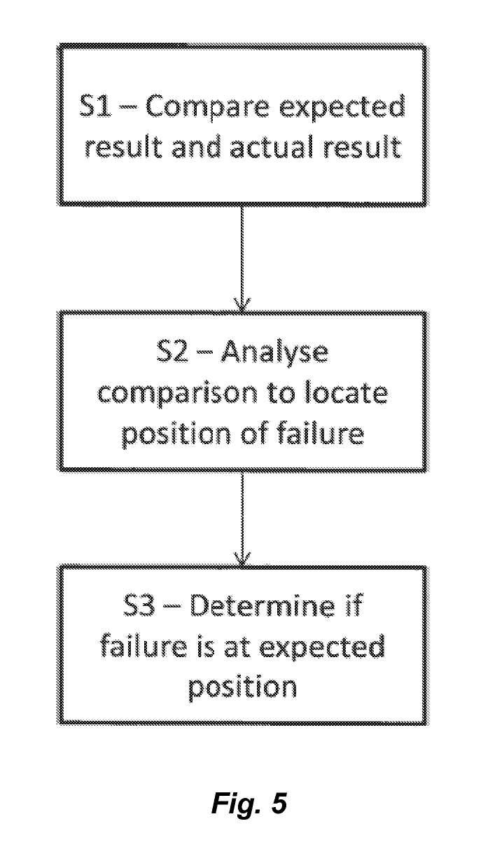

An embodiment of a method will now be described with reference to FIG. 5.

In step S1, a comparison is carried out between the expected results and the actual results as previously described. This may be carried out by the tester in some embodiments.

In step S2, an analysis is done on the comparison to locate the position of the failing flip-flops in the scan chain.

In step S3, a determination is made to see if the failure occurs at an expected location.

In some embodiments, steps S2 and S3 may be combined.

In some embodiments, steps S2 and S3 may be carried out by the ATPG tool.

This analysis may be done by any suitable analysis apparatus. For example, at least some of the analysis may be done by an analysis apparatus 53 of the ATPG tool or a separate apparatus. The analysis apparatus 53 may be implemented in hardware or special purpose circuits, software, logic or any combination thereof. Some aspects may be implemented in hardware, while other aspects may be implemented in firmware or software which may be executed by a controller, microprocessor or other computing device, although embodiments are not limited thereto.

A CAD/EDA (electronic design automation) tool may have the ability to insert circuitry such as previously described in a circuit design. This may be done automatically, for example during scan insertion/hookup. This would allow information to be put into scan support data. The information may comprise one or more of: how many; what instance name; which scan chain(s); which position in the chain. This may be later used when the ATPG tool is diagnosing scan fails, such that the ATPG tool could automatically confirm the validity of the scan fail diagnosis.

Some embodiments may be implemented by computer software executable by a data processor, or by hardware, or by a combination of software and hardware. The software may be stored on such physical media as memory chips, or memory blocks implemented within the processor, magnetic media such as hard disk or floppy disks, and optical media such as for example DVD and the data variants thereof, CD. The memory may be of any type suitable to the local technical environment and may be implemented using any suitable data storage technology, such as semiconductor-based memory devices, magnetic memory devices and systems, optical memory devices and systems, fixed memory and removable memory. A processor is provided by processor circuitry.

The device under test has been described as an integrated circuit. In other embodiments, the device under test may be a die.

The steps shown in FIG. 5 in some embodiments may be carried out by the same tool or by two or more different tools.

The various embodiments described above can be combined to provide further embodiments. Aspects of the embodiments can be modified, if necessary to employ concepts of the various patents, applications and publications to provide yet further embodiments. Other applications and configurations may be apparent to the person skilled in the art.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a plurality of scan chain blocks coupled together in series; and
reference circuitry inserted before one of the plurality of scan chain blocks and configured to:
in a scan mode of operation, receive a scan input signal;
in a test data capture mode of operation, receive a first known test signal value; and
in a scan out mode of operation, output the first known test signal value to the one scan chain block of the plurality of scan chain blocks.

2. The device of claim 1 wherein the reference circuitry is configured to, in the scan out mode of operation, output the received scan input signal to the one scan chain block after outputting the first known test signal value to the one scan chain block.

3. The device of claim 1 wherein said reference circuitry comprises a scan chain block of the plurality of scan chain blocks.

4. The device of claim 3 wherein the reference circuitry comprises a lock up latch configured to receive said first known test signal value from the scan chain block of the reference circuitry.

5. The device of claim 1, comprising a dedicated input pin, wherein said reference circuitry is configured to, in the test data capture mode of operation, receive said first known test signal value through the dedicated pin.

6. The device of claim 1 comprising a test register, wherein said reference circuitry is configured to, in the test data capture mode of operation, receive said first known test signal value from the test register.

7. The device of claim 1, comprising:
second reference circuitry inserted before another scan chain block of the plurality of scan chain blocks and configured to:
in the scan mode of operation, receive a second scan input signal;
in the test data capture mode of operation, receive a second known test signal value; and
in the scan out mode of operation, output the second known test signal value to the another scan chain block of the plurality of scan chain blocks.

8. The device of claim 7 wherein the second known test signal value is an inverse of the first known test signal value.

9. The device of claim 8, comprising an invertor configured to receive said first known test signal value and to output said second known test signal value.

10. The device of claim 1, comprising an integrated circuit including the plurality of scan chain blocks and the reference circuitry.

11. The device of claim 1, comprising a semiconductor die including the plurality of scan chain blocks and the reference circuitry.

12. The device of claim 1 wherein the plurality of scan chain blocks form a first scan chain of the device, the device comprising:
a second plurality of scan chain blocks coupled together in series and forming a second scan chain of the device; and
reference circuitry of the second scan chain inserted before one of the second plurality of scan chain blocks and configured to:
in the scan mode of operation, receive a second scan input signal;
in the test data capture mode of operation, receive a second known test signal value; and
in a scan out mode of operation, output the second known test signal value to the one scan chain block of the second plurality of scan chain blocks.

13. A system, comprising:
an input configured to receive information about a comparison between one or more test pattern outputs of a scan chain of a device under test and expected test pattern outputs; and
circuitry configured to determine whether a known reference point of the scan chain has a known test signal value which different from an expected test signal value based on said received information about the comparison.

14. The system of claim 13, comprising a comparator configured to compare the one or more test pattern outputs to the expected test pattern outputs.

15. The system of claim 14, comprising at least one signal translator coupled between the comparator and the circuitry.

16. The system of claim 13, wherein the circuitry is configured to generate control signals to control loading of the known test signal value into the known reference point of the scan chain.

17. A method, comprising:
receiving, by one or more configured processing devices, information about a comparison between one or more test pattern outputs of a scan chain of a device under test and expected test pattern outputs; and
determining, by the one or more configured processing devices, whether a known reference point of the scan chain has a known test signal value which different from an expected test signal value based on said received information about the comparison.

18. The method of claim 17, comprising comparing the one or more test pattern outputs to the expected test pattern outputs.

19. The method of claim 17, comprising loading of the known test signal value into the known reference point of the scan chain.

20. A non-transitory computer-readable memory medium having contents which when accessed by a processing system configure the processing system to perform a method, the method comprising:
analyzing a comparison of one or more test pattern outputs of a scan chain of a device under test and expected test pattern outputs; and
determining whether a known reference point of the scan chain has a known test signal value which different from an expected test signal value based on the analysis.

21. The medium of claim 20, wherein the method comprising comparing the one or more test pattern outputs to the expected test pattern outputs.

22. The medium of claim 20 wherein the method comprising loading of the known test signal value into the known reference point of the scan chain.
